(19) United States
(12) Patent Application Publication
(10) Pub. No.: US 2015/0129028 A1
(43) Pub. Date: May 14, 2015

(54) SOLAR CELL AND METHOD OF FABRICATING THE SAME

(71) Applicant: LG INNOTEK CO., LTD., Seoul (KR)

(72) Inventor: Jin Ho Gwon, Seoul (KR)

(73) Assignee: LG INNOTEK CO., LTD., Seoul (KR)

(21) Appl. No.: 14/403,470

(22) PCT Filed: Jul. 26, 2013
(86) PCT No.: PCT/KR2013/006752

§ 371 Date: Nov. 24, 2014

(30) Foreign Application Priority Data
Jul. 27, 2012 (KR) 10-2012-0082275

(51) Int. Cl. H01L 31/0224; H01L 31/05

(52) U.S. Cl. CPC H01L 31/02245; H01L 31/022475; H01L 31/0508
USPC 136/256

(57) ABSTRACT

A solar cell includes a substrate; a back electrode layer on the substrate; a light absorbing layer on the back electrode layer; and a buffer layer on the light absorbing layer. A first through hole is formed through the back electrode layer, a second through hole is formed through the buffer layer and the light absorbing layer, and the first through hole is overlapped with the second through hole.

### TECHNICAL FIELD

The embodiment relates to a solar cell and a method of fabricating the same.

### BACKGROUND ART

A method of fabricating a solar cell for solar light power generation is as follows. First, after preparing a substrate, a back electrode layer is formed on the substrate and patterned by a laser to form a plurality of back electrodes.

Thereafter, a light absorbing layer, a buffer layer, and a high resistance buffer layer are sequentially formed on the back electrodes. A scheme of forming a Cu(In,Ga)Se₂ (CIGS) based-light absorbing layer by simultaneously or separately evaporating copper (Cu), indium (In), gallium (Ga), and selenium (Se) and a scheme of performing a selenization process after a metallic precursor film has been formed, have been extensively used in order to form the light absorbing layer. The energy bandgap of the light absorbing layer is in the range of about 1 eV to 1.8 eV.

Then, the buffer layer including cadmium sulfide (CdS) is formed on the light absorbing layer through a sputtering process. The energy bandgap of the buffer layer may be in the range of about 2.2 eV to 2.4 eV. After that, the high resistance buffer layer including zinc oxide (ZnO) is formed on the buffer layer through the sputtering process. The energy bandgap of the high resistance buffer layer is in the range of about 3.1 eV to about 3.3 eV.

Thereafter, hole patterns may be formed in the light absorbing layer, the buffer layer, and the high resistance buffer layer.

Then, a transparent conductive material is laminated on the high resistance buffer layer, and the hole patterns are filled with the transparent conductive material. Accordingly, a transparent electrode layer is formed on the high resistance buffer layer, and connection wires are formed inside the hole patterns. A material constituting the transparent electrode layer and the connection wires may include aluminum doped zinc oxide (AZO). The energy bandgap of the transparent electrode layer may be in the range of about 3.1 eV to 3.3 eV.

Then, the hole pattern is formed in the transparent electrode layer, so that a plurality of solar cells may be formed. The transparent electrodes and the high resistance buffers correspond to the cells, respectively. The transparent electrodes and the high resistance buffers may be provided in the form of a stripe or a matrix.

The transparent electrodes and the back electrodes are misaligned from each other and electrically connected with each other by the connection wires. Accordingly, the solar cells may be electrically connected to each other in series.

As described above, in order to convert the solar light into electrical energy, various solar cell apparatuses have been fabricated and used. One of the solar cell apparatuses is disclosed in Korean Unexamined Patent Publication No. 10-2008-0088744.

Meanwhile, according to the related art, since a process of depositing the light absorbing layer is performed at a high temperature of 500° C., when the light absorbing layer is deposited, the support substrate may be bent. Accordingly, a first through hole formed through the back electrode layer may be bent together. Accordingly, the first through hole may be overlapped with a second through hole formed through the buffer layer and the light absorbing layer.

Therefore, in the process according to the related art, in order to prevent the first through hole from being overlapped with the second through hole by taking into consideration the bending of the first through hole, the first through hole is spaced apart from the second through hole by a sufficient interval.

However, as the interval between the first through hole and the second through hole is increased, a dead zone, in which power is generated, is increased, so that the efficiency of the solar cell is reduced.

Accordingly, a solar cell capable of reducing the dead zone by suitably adjusting the interval between the first through hole and the second through hole and a method of fabricating the same are required.

### DISCLOSURE OF INVENTION

### Technical Problem

The embodiment provides a solar cell having photoelectric conversion efficiency and a method of fabricating the same.

### Solution to Problem

According to the embodiment, there is provided a method of fabricating a solar cell. The method includes forming a back electrode layer on a substrate, forming a first through hole through the back electrode layer, forming a light absorbing layer on the back electrode layer, forming a buffer layer on the light absorbing layer, and forming a second through hole through the buffer layer and the light absorbing layer. A distance between the first through hole and the second through hole is about 40 μm or more.

According to the embodiment, there is provided a solar cell including a substrate, a back electrode layer on the substrate, a light absorbing layer on the back electrode layer, and a buffer layer on the light absorbing layer. A first through hole is formed through the back electrode layer, a second through hole is formed through the buffer layer and the light absorbing layer, and the first through hole is overlapped with the second through hole.

### Advantageous Effects of Invention

As described above, according to the solar cell and the method of fabricating the same, the interval between the first through holes and the second through holes is minimized, so that an inactive region, that is, a dead zone, in which power is not generated in the solar cell, can be reduced.

In other words, conventionally, when the first through holes TH1 and the second through holes TH2 are formed, the first through holes TH1 are spaced apart from the second through holes TH2 by the sufficient interval by taking the bending of the first through holes TH1 into consideration, so that the first through holes TH1 is not overlapped with the second through holes TH2, thereby increasing the dead zone.

However, according to the solar cell and the method of fabricating the same of the embodiment, the interval between the first through holes and the second through holes is minimized, so that a dead zone can be reduced. Accordingly, the whole efficiency of the solar cell can be improved.

### BRIEF DESCRIPTION OF DRAWINGS

FIG. 1 is a plan view showing a solar cell according to the embodiment.

FIG. 2 is a sectional view showing one section of the solar cell according to the embodiment.

FIGS. 3 to 5 are sectional views showing another section of the solar cell according to the embodiment.

FIGS. 6 to 12 are sectional views showing a method of fabricating the solar cell according to the embodiment.

### MODE FOR THE INVENTION

In the following description of the embodiments, it will be understood that, when a layer film, a region, a pattern or a structure is referred to as being “on” or “under” another substrate, layer film, region, pad or pattern, it can be “directly” or “indirectly” on the other substrate, layer film, region, pad, or pattern, or one or more intervening layers may also be present. Such a position of each layer will be described with reference to the drawings.

The thickness and size of each layer film, region, pattern or structure shown in the drawings may be modified for the purpose of convenience or clarity. In addition, the size of each layer film, region, pattern or structure does not utterly reflect an actual size.

Hereinafter, the embodiment will be described in detail with reference to accompanying drawings.

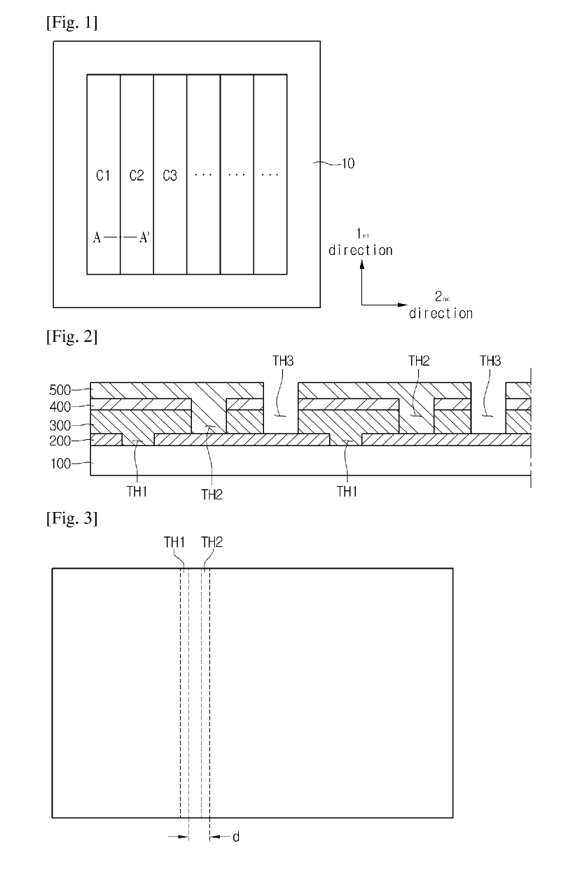

Hereinafter, a solar cell according to the embodiment will be described in detail with reference to FIGS. 1 to 10. FIG. 1 is a plan view showing the solar cell according to the embodiment, and FIG. 2 is a sectional view showing the solar cell according to the embodiment. FIGS. 3 to 10 are sectional views showing a method of fabricating the solar cell according to the embodiment.

Referring to FIGS. 1 to 5, the solar cell according to the embodiment includes a support substrate 100, a back electrode layer 200, a light absorbing layer 300, a buffer layer 400, and a front electrode layer 500.

The support substrate 100 has a plate shape and supports the back electrode layer 200, the light absorbing layer 300, the buffer layer 400, and the front electrode layer 500.

The support substrate 100 may include an insulator. The support substrate 100 may include a glass substrate, a plastic substrate, or a metallic substrate. In more detail, the support substrate 100 may include a soda lime glass substrate. Alternatively, the support substrate 100 may include a ceramic substrate including alumina, stainless steel, or polymer having a flexible property. The support substrate 100 may be transparent. The support substrate 100 may be rigid or flexible.

The back electrode layer 200 is provided on the support substrate 100. The back electrode layer 200 is a conductive layer, and the back electrode layer 200 may include one of molybdenum (Mo), gold (Au), aluminum (Al), chrome (Cr), tungsten (W), and copper (Cu). Among them, especially, Mo makes the lower difference in the thermal expansion coefficient from the support substrate 100 when comparing with the other elements, so that the Mo represents a superior adhesive property, thereby preventing the above de-lamination phenomenon.

In addition, the back electrode layer 200 may include at least two layers. In this case, the layers may include the same metal or different metals.

First through holes TH1 are formed in the back electrode layer 200. The first through holes TH1 will be described in detail later.

The light absorbing layer 300 is provided on the back electrode layer 200. A material constituting the light absorbing layer 300 is filled in the first through holes TH1.

The light absorbing layer 300 may include a group I-III-VI-based compound. For example, the light absorbing layer 300 may have a Cu(In,Ga)Se₂(CIGS) crystal structure, a Cu(In)Se₂ crystal structure, or a Cu(Ga)Se₂ crystal structure.

The light absorbing layer 300 may have an energy bandgap in the range of 1 eV to 1.8 eV.

The buffer layer 400 is provided on the light absorbing layer 300, and the buffer layer 400 directly makes contact with the light absorbing layer 300. The buffer layer 400 includes CdS, ZnS, In_{X}S_{Y}, In_{X}Se_{Y}Zn, O, and OH. The thickness of the buffer layer 400 may be in the range of about 50 nm to about 150 nm. The energy bandgap of the buffer layer 400 may be in the range of about 2.2 eV to about 2.4 eV.

The high-resistance buffer layer may be further provided on the buffer layer 400. The high-resistance buffer layer includes i-ZnO which is not doped with impurities. The energy bandgap of the high-resistance buffer layer may be in the range of about 3.1 eV to about 3.3 eV. In addition, the high-resistance buffer layer may be omitted.

The second through holes TH2 may be formed on the buffer layer 400. The second through holes TH2 will be described below.

The front electrode layer 500 is provided on the buffer layer 400. When the high-resistance buffer layer is formed, the front electrode layer 500 is provided on the high-resistance buffer layer. The front electrode layer 500 is transparent. The front electrode layer 500 is a conductive layer. In addition, the resistance of the front electrode layer 500 is higher than that of the back electrode layer 500.

The front electrode layer 500 includes oxide. For example, a material constituting the front electrode layer 500 may include Al doped zinc oxide (AZO), indium zinc oxide (IZO), or indium tin oxide (ITO).

The front electrode layer 500 may have the thickness in the range of about 500 nm to about 1.5 μm. In addition, if the front electrode layer 500 includes Al doped ZnO, the Al may be doped with the content of about 2.5 wt % to about 3.5 wt %.

The buffer layer 400 and the front electrode layer 500 are formed therein with third through hole TH3. The third through hole TH3 may be formed through a portion or an entire portion of the buffer layer 400, the high resistance buffer layer, and the front electrode layer 500. In other words, the third through hole TH3 may expose the top surface of the back electrode layer 200.

The third through hole TH3 are formed adjacent to the second through hole TH2. In detail, the third through hole TH3 are provided beside the second through hole TH2. In other words, when viewed in a plan view, the third through hole TH3 are provided in parallel to the second through hole TH2. The third through hole TH3 may have the shape extending in a first direction.

The third through holes TH3 are formed through the front electrode layer 500. In detail, the third through holes TH3 may be formed through portions or entire portions of the light absorbing layer 300 the buffer layer 400, and/or the high-resistance buffer layer.

The front electrode layer 500 is divided into a plurality of front electrodes by the third through hole TH3. In other words, the front electrodes are defined by the third through hole TH3.

Each front electrode has a shape corresponding to the shape of each back electrode. In other words, the front electrodes are arranged in the shape of a stripe. Alternatively, the front electrodes may be arranged in the shape of a matrix.

In addition, a plurality of solar cells C1, C2, . . . , and Cn are defined by the third through holes TH3. In detail, the solar cells C1, C2, . . . , and Cn are defined by the second and third through holes TH2 and TH3. In other words, the solar cell apparatus according to the embodiment is divided into the solar cells C1, C2, . . . , and Cn by the second and third through hole TH2 and TH3.

In other words, a solar cell panel 10 includes the support substrate 100 and the solar cells C1, C2, . . . , and Cn. The solar cells C1, C2, . . . , and Cn are provided in the support substrate 100 and spaced apart from each other by a predetermined interval.

Connection parts are provided in the second through holes TH2. The connection parts extend downward from the front electrode layer 500 while making contacting with the back electrode layer 200. For example, the connection parts extend from the front electrode of the first cell C1 to make contact with the back electrode of the second cell C2.

In addition, the connection parts connect solar cells adjacent to each other. The connection parts connect the front electrode and the back electrode included in the adjacent solar cells, respectively.

The connection parts are integrated with the front electrode layer 500. In addition, materials constituting the connection parts are the same as materials constituting the front electrode layer 500.

Hereinafter, the first through holes TH1 and the second through holes TH2 according to the embodiment will be described with reference to FIGS. 3 to 5.

The first through holes TH1 are open regions to expose the top surface of the support substrate 100. When viewed in a plan view, the first through holes TH1 may have the shape extending in the first direction. Each of the first through holes TH1 may have a width in a range of about 80 μm to about 200 μm, but the embodiment is not limited thereto.

The back electrode layer 200 is divided into a plurality of back electrodes by the first through holes TH1. In other words, the back electrodes are defined by the first through holes TH1.

The back electrodes are spaced apart from each other by the first through holes TH1. The back electrodes are arranged in the form of a stripe.

Alternatively, the back electrodes may be arranged in the form of a matrix. In this case, the first through holes TH1 may be provided in the form of a lattice when viewed in a plan view.

The second through holes TH2 are open regions to expose the top surface of the support substrate 100 and the top surface of the back electrode layer 200. The second through holes TH2 may be formed in parallel to the first through holes TH1. When viewed in a plan view, the second through holes TH2 may have the shape to extend in one direction. The second through holes TH2 may have the widths of about 100 μm to about 200 μm, but the embodiment is not limited thereto.

A plurality of buffer layers may be defined in the buffer layer 400 by the second through holes TH2. In other words, the buffer layer 400 is divided into the buffer layers by the second through holes TH2.

The first through holes TH1 may be spaced apart from the second through holes TH2 by a predetermined interval. In detail, the first through holes TH1 are partially overlapped with the second through holes TH2 while being partially spaced apart from each other.

Each of the first through holes TH1 is overlapped with each of the second through holes TH2 at both end portions thereof or at the central portions thereof. When each of the first through holes TH1 is overlapped with each of the second through holes TH2 at both end portions thereof, the first through holes TH1 may be spaced apart from the second through holes TH2 in the direction of extending toward both end portions thereof from the central portions thereof. In addition, when the first through holes TH1 are overlapped with the second through holes TH2 at the central portions thereof, the first through holes TH1 may be spaced apart from the second through holes TH2 in the direction of extending toward the central portions thereof from both end portions thereof.

In other words, the first through holes TH1 are spaced apart from the second through holes TH2 by a predetermined interval in the directions in which the first through holes TH1 are bent.

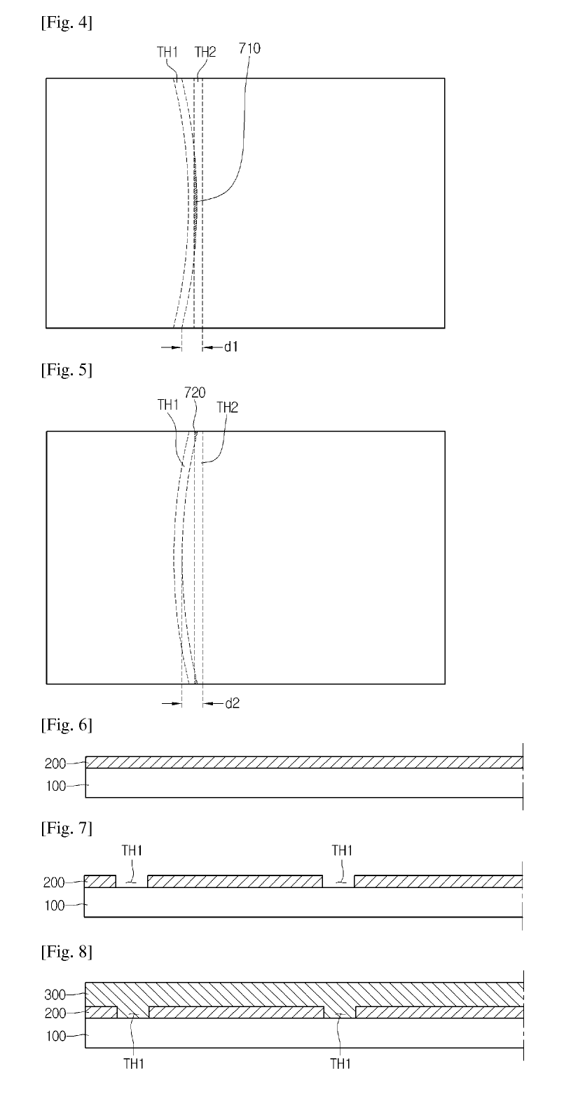

In this case, as shown in FIG. 4, when the first through holes TH1 are bent, the interval d1 between first through holes TH1 and the second through holes TH2 may be about 40 μm or more. Preferably, the interval d1 between the first through holes TH1 and the second through holes TH2 may be in the range of about 40 μm to about 200 μm.

In addition, as shown in FIG. 5, when the first through holes TH1 are bent, the interval d2 between the first through holes TH1 and the second through holes TH2 may be about 40 μm or more. Preferably, the interval d2 between the first through holes TH1 and the second through holes TH2 may be in the range of about 40 μm to about 200 μm.

In addition, the first through holes TH1 may be overlapped with the second through holes TH2 at a predetermined ratio. In detail, the second through holes TH2 may be overlapped with the first through holes TH1 by 1% to 20% based on the widths of the second through holes TH2. For example, when the width of the second through holes TH2 is 100 μm, the second through holes TH2 are overlapped with the first through holes TH1 by the width in the range of 1 μm to 40 μm.

The range of the overlap ratio between the first through holes TH1 and the second through holes TH2 are set by taking the efficiencies of the front electrode layer and the back electrode layer, which are connected with each other, by the second through holes TH2. In other words, when the second through holes TH2 is overlapped with the first through holes TH1 by 1% to 20%, the connection between front electrode layer and the back electrode layer is not affected. Accordingly, the whole efficiency of the solar cell is not reduced.

Although FIGS. 3 to 5 show one first through hole TH1 and one second through hole TH2 for the explanation of experience, the embodiment is not limited thereto. According to the embodiment, naturally, a plurality of first through holes TH1 and a plurality of second through holes TH2 may be formed.

In addition, the interval between the first through holes TH1 and the second through holes TH2 is minimized, so that an inactive region, that is, a dead zone, in which power is not generated in the solar cell, can be reduced.

In other words, conventionally, when the first through holes TH1 and the second through holes TH2 are formed, the first through holes TH1 are spaced apart from the second through holes TH2 by the sufficient interval by taking the bending of the first through holes TH1 into consideration, so that the first through holes TH1 is not overlapped with the second through holes TH2, thereby increasing the dead zone.

However, according to the solar cell of the embodiment, the interval between the first through holes TH1 and the second through holes TH2 is minimized, so that a dead zone in which power is not generated in the solar cell can be reduced. Accordingly, the whole efficiency of the solar cell can be improved.

Hereinafter, a method of fabricating the solar cell according to the embodiment will be described with reference to FIGS. 6 to 12. FIGS. 3 to 10 are views showing the method of fabricating the solar cell according to the embodiment. The above description of the solar cell will be in corporate in the description of the method of fabricating the solar cell.

Referring to FIG. 6, the back electrode layer 200 is formed on the support substrate 100. The back electrode layer 200 may be formed through a physical vapor deposition PVD or a plating scheme.

Thereafter, referring to FIG. 7, the first through hole TH1 are formed by patterning the back electrode layer 200. Accordingly, a plurality of back electrodes are formed on the support substrate 100. The back electrode layer 200 is patterned by a laser.

Each first through hole TH1 may expose the top surface of the support substrate 100, and have the width of about 80 μm to about 200 μm, but the embodiment is not limited thereto.

In addition, an additional layer such as an anti-diffusion layer may be interposed between the support substrate 100 and the back electrode layer 200. In this case, the first through hole TH1 expose the top surface of the additional layer.

Thereafter, referring to FIG. 8, the light absorbing layer 300 is formed on the back electrode layer 200. The light absorbing layer 300 may be formed a sputtering process or an evaporation scheme.

For example, in order to form the light absorbing layer 300, a scheme of forming a Cu(In,Ga)Se₂(CIGS) based-light absorbing layer 300 by simultaneously or separately evaporating Cu, In, Ga, and Se and a scheme of performing a selenization process after forming a metallic precursor film have been extensively performed.

Regarding the details of the selenization process after forming the metallic precursor layer, the metallic precursor layer is formed on the back electrode through a sputtering process employing a Cu target, an In target, or a Ga target.

Thereafter, the metallic precursor layer is subject to the selenization process so that the Cu(In,Ga)Se₂(CIGS) based-light absorbing layer 300 is formed.

Alternatively, the sputtering process employing the Cu target, the In target, and the Ga target and the selenization process may be simultaneously performed.

Alternatively, a CIS or a CIG light absorbing layer 300 may be formed through a sputtering process employing only Cu and In targets or only Cu and Ga targets and the selenization process.

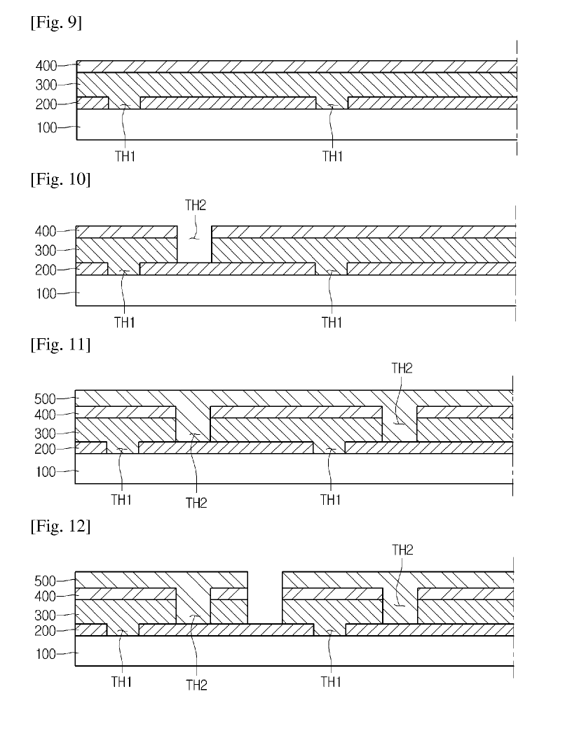

Thereafter, referring to FIG. 9, the buffer layer 400 is formed on the light absorbing layer 300. The buffer layer 400 may be formed through various schemes which are generally known as schemes of forming a buffer layer of a solar cell to those skilled in the art. For example, the buffer layer 400 may be formed through one selected from the group consisting of a sputtering scheme, an evaporation scheme, a CVD (chemical vapor deposition) scheme, an MOCVD (metal organic chemical vapor deposition) scheme, a CSS (close-spaced sublimation) scheme, a spray pyrolysis scheme, a chemical spraying scheme, a screen printing scheme, a vacuum-free liquid-phase film deposition, a CBD (chemicalbath deposition) scheme, a VTD (vapor transport deposition) scheme, an ALD (atomic layer deposition) scheme and an electrode-de-position scheme. In more detail, the buffer layer 400 may be formed the CBD scheme, an ALD scheme, or an MOCVD scheme.

Thereafter, zinc oxide is deposited on the buffer layer 400 through a deposition process, and a high-resistance buffer layer may be further formed. The high-resistance buffer layer may be formed by depositing diethylzinc (DEZ) and H2O.

The high-resistance buffer layer may be formed through a chemical vapor deposition, (CVD) scheme, a metal organic chemical vapor deposition (MOCVD) scheme, or an atomic layer deposition (ALD). Preferably, the high-resistance buffer layer may be formed through an MOCVD scheme.

Thereafter, referring to FIG. 10, portions of the light absorbing layer 300 and the buffer layer 400 are removed to form the second through holes TH2.

The second through holes TH2 may be formed by a mechanical device such as a tip or a laser device.

For example, the light absorbing layer 300 and the buffer layer 400 and/or the high-resistance buffer layer may be patterned by a tip having a width of about 40 μm to about 180 μm. In addition, the second through hole TH2 may be formed by a laser having a wavelength of about 200 nm to about 600 nm.

In this case, the second through hole TH2 may have the width of about 100 μm to about 200 μm. In addition, the second through hole TH2 exposes a portion of the top surface of the back electrode layer 200.

In this case, the second through holes TH2 may be partially spaced apart from the first through holes TH1, and partially overlapped with the first through holes TH1. In detail, the first through holes TH1 and the second through holes TH2 may have the interval of about 40 μm or more. In more detail, the first through holes TH1 and the second through holes TH2 may have the interval in the range of about 40 μm to about 200 μm.

In other words, in the step of forming the light absorbing layer 300, the first through holes TH1 may be bent in a predetermined direction as shown in FIG. 4 or FIG. 5. In other words, the second through holes TH2 and the first through holes TH1 may be overlapped with each other at the central portion thereof or at both end portions thereof according to the bending directions of the first through holes TH1.

In addition, the second through holes TH2 may be overlapped with the first through holes TH1 by 1% to 40% based on the full width of the second through holes TH2.

Thereafter, referring to FIG. 11, the front electrode layer may be formed on the buffer layer 400. For example, the front electrode layer 800 may be formed through an RF sputtering scheme using a ZnO target, a reactive sputtering scheme using a Zn target, or an MOCVD.

Thereafter, referring to FIG. 12, the third through holes TH3 are formed by removing portions of the light absorbing layer 300, the buffer layer 400, and the front electrode layer 500. Accordingly, a plurality of front electrodes, a first cell C1, a second cell C2, and a third cell C3 are defined by patterning the front electrode layer 500. The third through holes TH3 have the width in the range of about 80 μm to about 200 μm.

As described above, according to the method of fabricating the solar cell according to the embodiment, the interval between the first through holes TH1 and the second through holes TH2 is minimized, so that an inactive region, that is, a dead zone, in which power is not generated in the solar cell, can be reduced. Accordingly, the whole efficiency of the solar cell can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. (canceled)

2. (canceled)

3. (canceled)

4. (canceled)

5. (canceled)

6. A solar cell comprising:
a substrate;
a back electrode layer on the substrate;
a light absorbing layer on the back electrode layer; and
a buffer layer on the light absorbing layer,
wherein a first through hole is formed through the back electrode layer, a second through hole is formed through the buffer layer and the light absorbing layer, and the first through hole is overlapped with the second through hole.

7. The solar cell of claim 6, wherein the first through hole has a width in a range of 80 μm to 200 μm, and the second through hole has a width in a range of 100 μm to 200 μm.

8. The solar cell of claim 7, wherein the first through hole and the second through hole are overlapped with each other by about 1% to about 20% based on a full width of the second through hole.

9. The solar cell of claim 8, wherein the first through hole and the second through hole extend in one direction in parallel.

10. The solar cell of claim 9, wherein a distance between the first through hole and the second through hole is 40 μm or more.

11. The solar cell of claim 10, wherein the interval between the first through hole and the second through hole is in a range of 40 μm to 200 μm.

12. The solar cell of claim 6, wherein the first through holes are overlapped with each of the second through holes at both end portions thereof or at the central portions thereof.

13. The solar cell of claim 12, wherein each of the first through holes is overlapped with each of the second through holes at both end portions thereof, the first through holes spaced apart from the second through holes in the direction of extending toward both end portions thereof from the central portions thereof.

14. The solar cell of claim 13, wherein each of the first through holes is overlapped with the second through holes at the central portions thereof, the first through holes spaced apart from the second through holes in the direction of extending toward the central portions thereof from both end portions thereof.
